(19) United States
(12) Patent Application Publication
(10) Pub. No.: US 2025/0294836 A1
(43) Pub. Date: Sep. 18, 2025

(54) SEMICONDUCTOR DEVICE AND METHOD FOR MANUFACTURING THE SAME

(71) Applicant: DENSO CORPORATION, Kariya-city (JP)

(72) Inventor: Hidefumi TAKAYA, Kariya-city (JP)

(21) Appl. No.: 19/226,570

(22) Filed: Jun. 3, 2025

Related U.S. Application Data
(63) Continuation of application No. PCT/JP2023/033260, filed on Sep. 12, 2023.

(30) Foreign Application Priority Data
Dec. 7, 2022 (JP) 2022-195676

(51) Int. Cl. H10D 62/60; H10D 30/01; H10D 30/66; H10D 62/10

(52) U.S. Cl. CPC H10D 62/60; H10D 30/0297; H10D 30/668; H10D 62/102; H10D 62/124

(57) ABSTRACT

A semiconductor device includes a semiconductor layer with a super junction structure in which a first column of a first conductivity type and a second column of a second conductivity type are alternately and repeatedly arranged at least in one direction. The first column includes a first column high-concentration layer and a first column low-concentration layer that is disposed adjacent to the first column high-concentration layer in the at least one direction and has a carrier concentration lower than that of the first column high-concentration layer.

### CROSS REFERENCE TO RELATED APPLICATIONS

The present application is a continuation application of International Patent Application No. PCT/JP2023/033260 filed on Sep. 12, 2023, which designated the U.S. and claims the benefit of priority from Japanese Patent Application No. 2022-195676 filed on Dec. 7, 2022. The entire disclosures of all of the above applications are incorporated herein by reference.

### TECHNICAL FIELD

The present disclosure relates to a semiconductor device and a method for manufacturing the same.

### BACKGROUND

As a structure that achieves both low on-resistance and high breakdown voltage in a semiconductor device, a super junction structure having n-type columns and p-type columns alternately arranged in a repeating manner in at least one direction has been proposed.

### SUMMARY

The present disclosure provides a semiconductor device and a method for manufacturing the semiconductor device. According to an aspect, a semiconductor device may include a semiconductor layer having a super junction structure in which a a first column of a first conductivity type and a second column of a second conductivity type are alternately and repeatedly arranged in at least one direction. The first column may include a first column high-concentration layer and a first column low-concentration layer that is adjacent to the first column high-concentration layer in the at least one direction and has a carrier concentration lower than a carrier concentration of the first column high-concentration layer.

### BRIEF DESCRIPTION OF DRAWINGS

Features and advantages of the present disclosure will become more apparent from the following detailed description made with reference to the accompanying drawings, in which:

FIG. 1 is a schematic cross-sectional view of a main part of a semiconductor device according to a first embodiment of the present disclosure;

FIG. 2 is a schematic cross-sectional view of a main part in a process of manufacturing the semiconductor device shown in FIG. 1;

FIG. 3 is a schematic cross-sectional view of a main part in a process of manufacturing the semiconductor device shown in FIG. 1;

FIG. 4 is a schematic cross-sectional view of a main part in a process of manufacturing the semiconductor device shown in FIG. 1;

FIG. 5 is a schematic cross-sectional view of a main part in a process of manufacturing the semiconductor device shown in FIG. 1;

FIG. 6 is a schematic cross-sectional view of a main part in a process of manufacturing the semiconductor device shown in FIG. 1;

FIG. 7 is a schematic cross-sectional view of a main part of a semiconductor device according to a second embodiment of the present disclosure; and

FIG. 8 is a schematic cross-sectional view of a main part of a semiconductor device according to a third embodiment of the present disclosure.

### DETAILED DESCRIPTION

In a semiconductor device having a super junction structure, in order to further improve the balance between low on-resistance and high breakdown voltage, it is necessary to increase the impurity concentrations of the n-type column and the p-type column. In a case where the impurity concentration of the n-type column and the impurity concentration of the p-type column are both high, it is difficult to form the n-type column and the p-type column by counter-doping p-type ions into an n-type semiconductor layer, for example. This is because a large number of p-type ions needs to be ion-implanted into the n-type semiconductor layer having the high impurity concentration, which causes issues such as defects. Therefore, to manufacture a semiconductor device that achieves both the low on-resistance and the high breakdown voltage, it is necessary to form each of the n-type column and the p-type column by ion implantation. In the case where each of the n-type column and the p-type column is formed by the ion implantation, if a positional deviation occurs between the n-type columns and the p-type columns in a repetition direction along which the n-type columns and the p-type columns are alternately arranged in a repeating manner, the charge balance between the n-type column and the p-type column may be disrupted. As a result, there will be a situation where the desired characteristics cannot be exhibited.

The present disclosure provides a technique for suppressing disruption of the charge balance between n-type columns and p-type columns in a semiconductor device having a super junction structure.

The present disclosure provides a semiconductor device. According to an aspect, the semiconductor device may include a semiconductor layer having a super junction structure in which a first column of a first conductivity type and a second column of a second conductivity type are alternately and repeatedly arranged in at least one direction. The first column may include a first column high-concentration layer and a first column low-concentration layer that is adjacent to the first column high-concentration layer in the at least one direction and has a carrier concentration lower than a carrier concentration of the first column high-concentration layer. In this configuration, the first column may be an n-type column while the second column may be a p-type column. Alternatively, the first column may be a p-type column while the second column may be an n-type column. The second column may include a second column high-concentration layer and a second column low-concentration layer. In such a semiconductor device, the charge amount of the first column substantially depends on the first column high-concentration layer. Therefore, if the first column high-concentration layer is formed at a position without overlapping with the second column, the charge amount of the first column will be a desired value. In such a semiconductor device, since the first column low-concentration layer is disposed adjacent to the first column high-concentration layer, a positional deviation of the first column high-concentration layer can be absorbed in the range of the first column low-concentration layer. Therefore, even if the first column high-concentration layer is misaligned, it is less likely that the first column high-concentration layer will be formed at a position overlapping with the second column. As a result, since the charge amount of the first column can be a desired value, the disruption of the charge balance between the first column and the second column can be suppressed.

The present disclosure provides a method for manufacturing the semiconductor device described above. According to an aspect, a method for manufacturing the semiconductor device may include: forming a first shielding layer on a surface of the semiconductor layer, the first shielding layer having an opening corresponding to a formation range where the first column is to be formed; measuring a misalignment of the first shielding layer; injecting ions into the semiconductor layer through the opening of the first shielding layer; forming a second shielding layer on the surface of the semiconductor layer, the second shielding layer having an opening corresponding to a formation range where the first column high-concentration layer is to be formed according to the measured misalignment; and injecting ions into the semiconductor layer through the opening of the second shielding layer. In the method according to the aspect described above, since the misalignment of the first shielding layer is measured when the first shielding layer is formed, it is possible to understand the tendency of misalignment of the first shielding layer. Thus, by forming the second shielding layer under a condition that suppresses the tendency of the misalignment, it is possible to suppress misalignment of the second shielding layer. As a result, the positional deviation of the first column high-concentration layer can be suppressed.

According to another aspect, a method for manufacturing the semiconductor device described above may include: forming a first shielding layer on a surface of the semiconductor layer, the first shielding layer having an opening corresponding to a formation range where the first column is to be formed; measuring a width of the opening of the first shielding layer; implanting ions into the semiconductor layer through the opening of the first shielding layer; forming a second shielding layer on the surface of the semiconductor layer, the second shielding layer having an opening corresponding to a formation range where the first column high-concentration layer is to be formed according to the measured width of the opening of the first shielding layer; and implanting ions into the semiconductor layer through the opening of the second shielding layer. In the method according to the aspect described above, since the width of the opening of the first shielding layer is measured when the first shielding layer is formed, it is possible to ascertain the tendency of the width of the opening whether the width of the opening tends to be wider or narrower relative to a design value. By forming the second shielding layer under a condition that suppresses the tendency of the width of the opening, it is possible to form the opening of the second shielding layer with the size approximate to a design value. As a result, it is possible to make the charge amount of the first column high-concentration layer the desired value.

Embodiments of the present disclosure will be described hereinafter with reference to the drawings. In the following descriptions, the same elements throughout the embodiments are denoted by the same reference numerals, and descriptions thereof will not be repeated. In addition, for the elements that are repeatedly arranged, the reference numeral is assigned to only one for the sake of clarity in the illustrations.

### First Embodiment

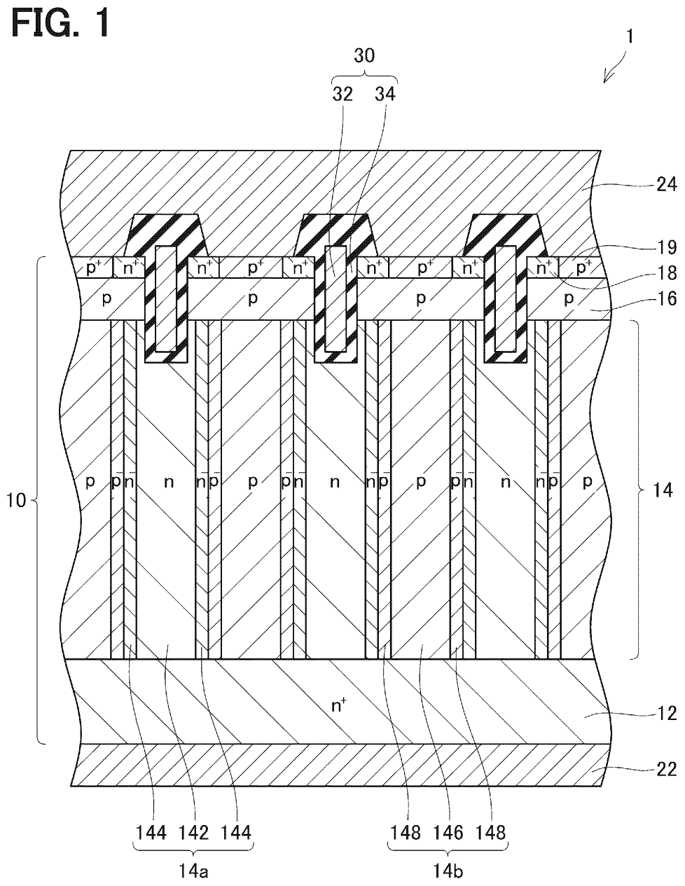

FIG. 1 schematically shows a cross-sectional view of a main part of a semiconductor device 1. The semiconductor device 1 is a power semiconductor device of a type which is referred to as a metal oxide semiconductor field effect transistor (MOSFET). The semiconductor device 1 includes a semiconductor layer 10, a drain electrode 22 covering a lower surface of the semiconductor layer 10, a source electrode 24 covering an upper surface of the semiconductor layer 10, and multiple trench gates 30 disposed in an upper layer portion of the semiconductor layer 10.

The semiconductor layer 10 is not particularly limited, but may be, for example, a 4H silicon carbide layer. The semiconductor layer 10 may have an upper surface with a crystal plane inclined by an off angle with respect to a (0001) Si plane. The off angle is not particularly limited, but may be, for example, 4°. The semiconductor layer 10 may be a silicon layer, a nitride semiconductor layer, or a gallium oxide layer, in place of the silicon carbide layer. The semiconductor layer 10 includes an n⁺-type drain region 12, an n-type drift region 14, a p-type body region 16, an n⁺-type source region 18, and a p⁺-type body contact region 19.

The drain region 12 is disposed in a lower layer portion of the semiconductor layer 10. The drain region 12 is disposed at a position exposed on the lower surface of the semiconductor layer 10. The drain region 12 is in ohmic contact with the drain electrode 22 that covers the lower surface of the semiconductor layer 10.

The drift region 14 is disposed between the drain region 12 and the body region 16. The drift region 14 includes a plurality of n-type columns 14a and a plurality of p-type columns 14b. The n-type columns 14a and the p-type columns 14b are arranged alternately at least in one direction in a repeating manner in the cross-section of the semiconductor layer 10 to form a super junction structure. Hereinafter, the direction in which the n-type columns 14a and the p-type columns 14b are arranged alternately in the repeating manner in the cross-section of the semiconductor layer 10 will be referred to as a “repetition direction”. Although not particularly limited, the n-type columns 14a and the p-type columns 14b may be arranged in a stripe pattern, when viewed in a direction perpendicular to the upper surface of the semiconductor layer 10, that is, in a plan view.

The n-type column 14a includes an n-type column high-concentration layer 142 and a pair of n-type column low-concentration layers 144. The n-type column high-concentration layer 142 extends between the drain region 12 and the body region 16 and has a flat plate-like shape. The pair of n-type column low-concentration layers 144 also extend between the drain region 12 and the body region 16 and each of the n-type column low-concentration layers 144 has a flat plate-like shape. The pair of n-type column low-concentration layers 144 are in contact with opposite side surfaces of the n-type column high-concentration layer 142 in the repetition direction. The carrier concentration of the n-type impurity in the n-type column low-concentration layer 144 is lower than the carrier concentration of the n-type impurity in the n-type column high-concentration layer 142. The carrier concentration of the n-type impurity in the n-type column low-concentration layer 144 is not particularly limited. For example, the carrier concentration of the n-type impurity in the n-type column low-concentration layer 144 may be one-fifth or less of the carrier concentration of the n-type impurity in the n-type column high-concentration layer 142. Further, the carrier concentration of the n-type impurity in the n-type column low-concentration layer 144 may be one-tenth or less of the carrier concentration of the n-type impurity in the n-type column high-concentration layer 142. When the carrier concentration of the n-type impurity is measured along the repetition direction, it is confirmed that an inflection point is present between the n-type column high-concentration layer 142 and the n-type column low-concentration layer 144, and that there are at least two layers with different carrier concentrations, the n-type column high-concentration layer 142 and the n-type column low-concentration layer 144, in the n-type column 14a. The width of the n-type column low-concentration layer 144 is smaller than the width of the n-type column high-concentration layer 142 in the repetition direction.

The p-type column 14b includes a p-type column high-concentration layer 146 and a pair of p-type column low-concentration layers 148. The p-type column high-concentration layer 146 extends between the drain region 12 and the body region 16 and has a plate-like shape. The pair of p-type column low-concentration layers 148 also extend between the drain region 12 and the body region 16 and each of the p-type column low-concentration layers 148 has a plate-like shape. The p-type column low-concentration layers 148 are in contact with opposite side surfaces of the p-type column high-concentration layer 146 in the repetition direction. The carrier concentration of the p-type impurity in the p-type column low-concentration layer 148 is lower than the carrier concentration of the p-type impurity in the p-type column high-concentration layer 146. The carrier concentration of the p-type impurity in the p-type column low-concentration layer 148 is not particularly limited. For example, the carrier concentration of the p-type impurity in the p-type column low-concentration layer 148 may be one-fifth or less of the carrier concentration of the p-type impurity in the p-type column high-concentration layer 146. Further, the carrier concentration of the p-type impurity in the p-type column low-concentration layer 148 may be one-tenth or less of the carrier concentration of the p-type impurity in the p-type column high-concentration layer 146. When the carrier concentration of the p-type impurity is measured along the repetition direction, it is confirmed that an inflection point is present between the p-type column high-concentration layer 146 and the p-type column low-concentration layer 148, and that there are at least two layers with different carrier concentrations, the p-type column high-concentration layer 146 and the p-type column low-concentration layer 148, in the p-type column 14b. The width of the p-type column low-concentration layer 148 is smaller than the width of the p-type column high-concentration layer 146 in the repetition direction.

In a manufacturing method described below, the n-type column high-concentration layer 142, the n-type column low-concentration layer 144, the p-type column high-concentration layer 146, and the p-type column low-concentration layer 148 are each formed by ion implantation. However, either the n-type column low-concentration layer 144 or the p-type column low-concentration layer 148 may be an epitaxial layer.

When the drift region 14 is depleted, the n-type columns 14a are positively charged and the p-type columns 14b are negatively charged. When the amount of positive charge in the n-type column 14a and the amount of negative charge in the p-type column 14b are balanced at a high concentration, the drift region 14 is effectively depleted, thereby improving the breakdown voltage of the semiconductor device 1. In the semiconductor device 1, the charge amount in the n-type column 14a depends on the n-type column high-concentration layer 142, which is high in concentration and wide. Similarly, in the semiconductor device 1, the charge amount in the p-type column 14b depends on the p-type column high-concentration layer 146, which is high in concentration and wide. Therefore, the semiconductor device 1 is designed so that charge balance is achieved between the n-type column high-concentration layer 142 and the p-type column high-concentration layer 146.

The body region 16 is disposed on the drift region 14. The body region 16 is disposed in the upper layer portion of the semiconductor layer 10. The body region 16 is disposed between the n-type column 14a of the drift region 14 and the source region 18. The body region 16 is in contact with both the n-type column 14a and the source region 18, and separates the n-type column 14a from the source region 18. The carrier concentration of the p-type impurity in the body region 16 is adjusted according to a desired gate threshold voltage.

The source region 18 is disposed on the body region 16. The source region 18 is disposed in the upper layer portion of the semiconductor layer 10, and is located at a position exposed on the surface of the semiconductor layer 10. The source region 18 is in contact with the side surface of the trench gate 30. The source region 18 is in ohmic contact with the source electrode 24, which covers the surface of the semiconductor layer 10.

The body contact region 19 is disposed on the body region 16. The body contact region 19 is disposed in the upper layer portion of the semiconductor layer 10, and is located at a position exposed on the surface of the semiconductor layer 10. The body contact region 19 is in ohmic contact with the source electrode 24, which covers the surface of the semiconductor layer 10.

The trench gate 30 is filled in a trench formed in the upper layer portion of the semiconductor layer 10. The trench gate 30 penetrates the source region 18 and the body region 16, and reaches the n-type column 14a of the drift region 14. In this example, the trench gate 30 extends along the longitudinal directions of the n-type column 14a and the p-type column 14b when the semiconductor layer 10 is viewed from above, that is, in the plan view. Alternatively, the trench gate 30 may extend along the repetition direction of the n-type columns 14a and the p-type columns 14b, that is, along a direction perpendicular to the longitudinal directions of the n-type columns 14a and the p-type columns 14b, when the semiconductor layer 10 is viewed in the plan view. The trench gate 30 includes a gate electrode 32 and a gate insulating film 34. The gate electrode 32 is formed of polysilicon containing an impurity. The gate electrode 32 faces the semiconductor layer 10 through the gate insulating film 34. Specifically, the gate electrode 32 faces a portion of the body region 16 through the gate insulating film 34, the portion separating the n-type column 14a of the drift region 14 from the source region 18. The gate insulating film 34 is formed of a silicon oxide. The gate insulating film 34 covers the inner wall of the trench.

Next, an operation of the semiconductor device 1 will be described with reference to FIG. 1. In a state where the potential of the drain electrode 22 is more positive than the potential of the source electrode 24, when the potential of the gate electrode 32 of the trench gate 30 is controlled to be more positive than the source electrode 24 and higher than the threshold value, the semiconductor device 1 turns on. At this time, an inversion layer is formed in the portion of the body region 16, the portion separating the source region 18 and the n-type column 14a of the drift region 14. Electrons supplied from the source region 18 reach the n-type column 14a of the drift region 14 via the channel of the inversion layer. The electrons that have reached the n-type column 14a flow to the drain region 12 from the n-type column 14a. Since the n-type column 14a has the n-type column high-concentration layer 142 having the high carrier concentration of the n-type impurity, the semiconductor device 1 can have the characteristic of low on-resistance.

When the potential of the gate electrode 32 of the trench gate 30 is controlled to be the same as the potential of the source electrode 24, the channel of the inversion layer disappears, and the semiconductor device 1 turns off. The multiple n-type columns 14a and the multiple p-type columns 14b, which form the super junction structure, are substantially fully depleted. As a result, the drift region 14 is depleted in a wide area. Since the drift region 14 has the super junction structure, the electric field distribution in the drift region 14 is leveled in the thickness direction. Since the drift region 14 can withstand a large potential difference, the semiconductor device 1 can thus have the characteristic of high breakdown voltage.

Next, a process of forming the super junction structure in the manufacturing method of the semiconductor device 1 will be described. The other processes of the manufacturing method for manufacturing the semiconductor device 1 can employ known manufacturing techniques.

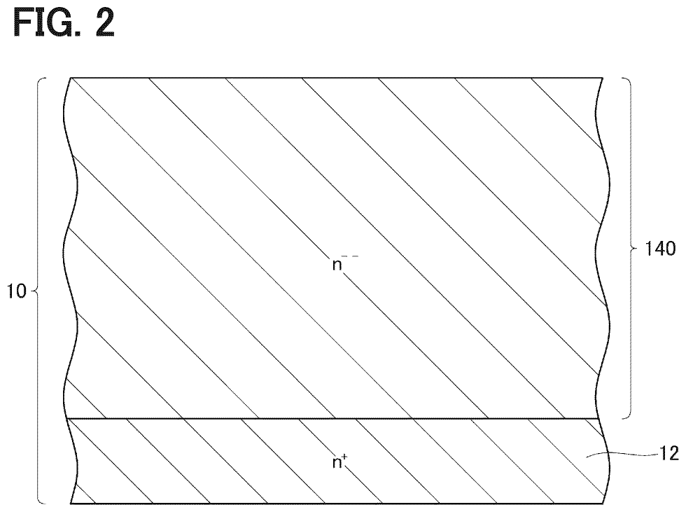

First, as shown in FIG. 2, the drain region 12, which is composed of the n⁺-type silicon carbide substrate, is prepared. Next, the n-type epitaxial layer 140 of silicon carbide is grown from the surface of the drain region 12 by an epitaxial growth technique, such as a chemical vapor deposition (CVD), though not particularly limited. It should be noted that the epitaxial layer 140 forms at least a part of the semiconductor layer 10, and the epitaxial layer 140 may also be referred to as the semiconductor layer.

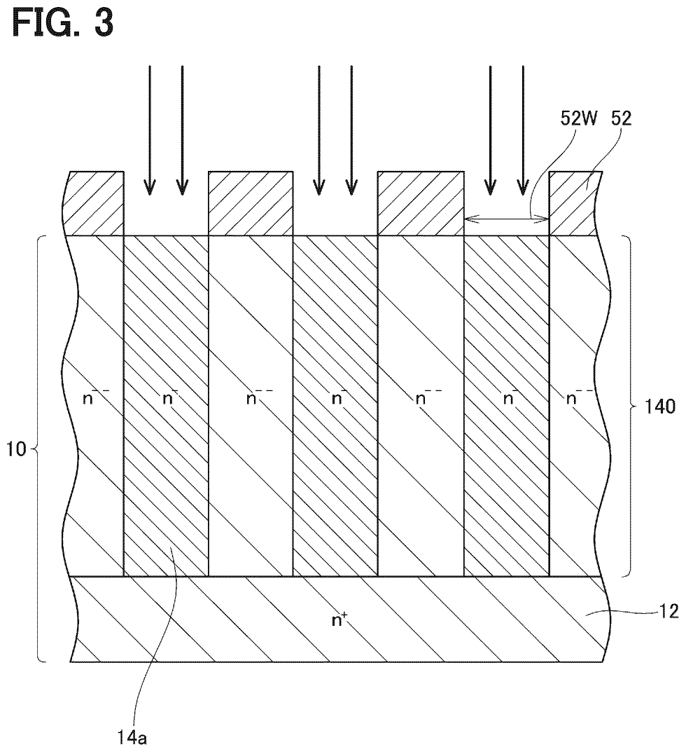

Next, as shown in FIG. 3, a shielding layer 52 is formed on the epitaxial layer 140 using a photolithography technique. It should be noted that the shielding layer 52 is an example of a first shielding layer. The shielding layer 52 is patterned to have openings corresponding to formation ranges where the n-type columns 14a are to be formed, which may also be referred to as n-type column formation ranges. Here, an opening width 52W of the shielding layer 52 is measured. The opening width 52W of the shielding layer 52 is the width of the opening of the shielding layer 52 in a short side direction of the opening and corresponds to the width of the opening in the repetition direction of the super junction structure. Next, n-type low-concentration layers are formed by implanting n-type impurity ions into the epitaxial layer 140 through the openings of the shielding layer 52 using an ion implantation technique. As will be described later, a part of the n-type low-concentration layer becomes the n-type column low-concentration layer 144. The n-type impurity ions are not particularly limited, but nitrogen ions may be used, for example. After the ion implantation, the shielding layer 52 is removed.

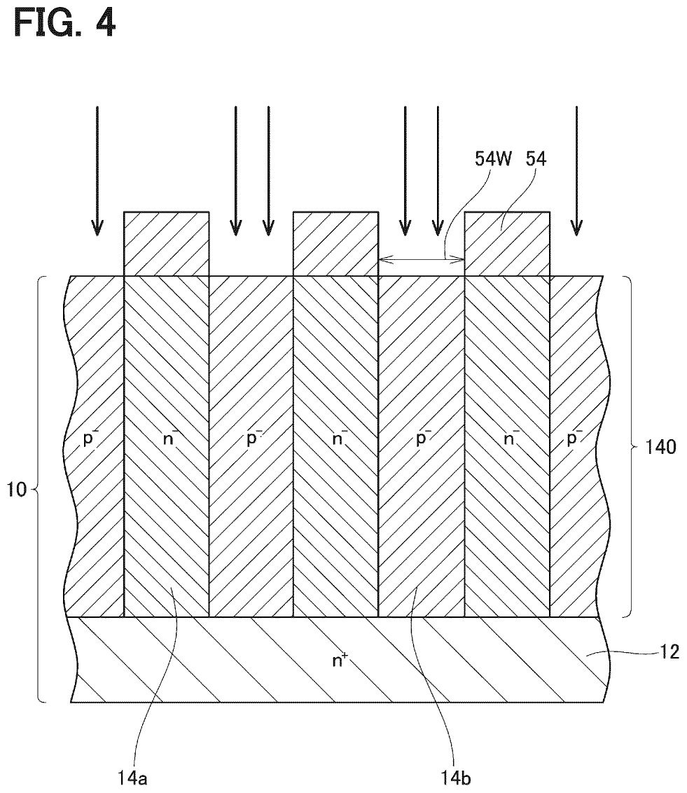

Next, as shown in FIG. 4, a shielding layer 54 is formed on the epitaxial layer 140 using a photolithography technique. It should be noted that the shielding layer 54 is an example of the first shielding layer. The shielding layer 54 is patterned to have openings corresponding to formation ranges where the p-type columns 14b are to be formed, which may also be referred to as the p-type column formation ranges. Here, an opening width 54W of the shielding layer 54 is measured. The opening width 54W of the shielding layer 54 is the width of the opening of the shielding layer 54 in a short side direction of the shielding layer 54, and corresponds to the width of the opening in the repetition direction of the super junction structure. Next, p-type low-concentration layers are formed by implanting p-type impurity ions into the epitaxial layer 140 through the openings of the shielding layer 54 using an ion implantation technique. As will be described later, a part of the p-type low-concentration layer becomes the p-type column low-concentration layer 148. The p-type impurity ions are not particularly limited, but aluminum ions may be used, for example. After the ion implantation, the shielding layer 54 is removed. It should be noted that the p-type low-concentration layers formed corresponding to the formation ranges of the p-type columns 14b may be formed prior to the n-type low-concentration layers formed corresponding to the formation ranges of the n-type columns 14a.

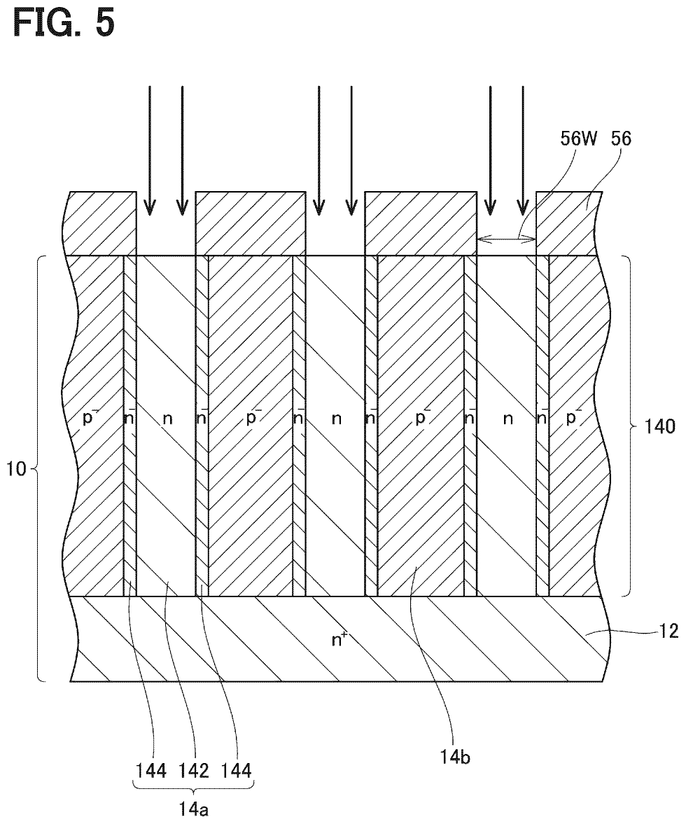

Next, as shown in FIG. 5, a shielding layer 56 is formed on the epitaxial layer 140 using a photolithography technique. It should be noted that the shielding layer 56 is an example of a second shielding layer. The shielding layer 56 is patterned to have openings corresponding to the formation ranges of the n-type column high-concentration layers 142. Here, multiple types of photomasks for exposing the shielding layer 56 are prepared and an appropriate type of photomask is selected according to the previously measured opening width 52W of the shielding layer 52 (see FIG. 3). For example, when the measured opening width 52W of the shielding layer 52 is greater than a design value, the opening width tends to be greater than the design value. In this case, therefore, a type of photomask having the opening width smaller than the design value is selected for exposing the shielding layer 56. On the other hand, when the measured opening width 52W of the shielding layer 52 is smaller than the design value, the opening width tends to be smaller than the design value. In this case, therefore, a type of photomask having the opening width greater than the design value is selected for exposing the shielding layer 56. As a result, it is possible to make the opening width 56W of the shielding layer 56 closer to the design value. Next, the n-type column high-concentration layer 142 is formed by implanting n-type impurity ions into the epitaxial layer 140 through the openings of the shielding layer 56 using an ion implantation technique. The n-type impurity ions are not particularly limited, and, for example, nitrogen ions may be used. As described above, since the opening width 56W of the shielding layer 56 is close to the design value, the carrier concentration of the n-type impurity in the n-type column high-concentration layer 142 is the desired value. After the ion implantation, the shielding layer 56 is removed.

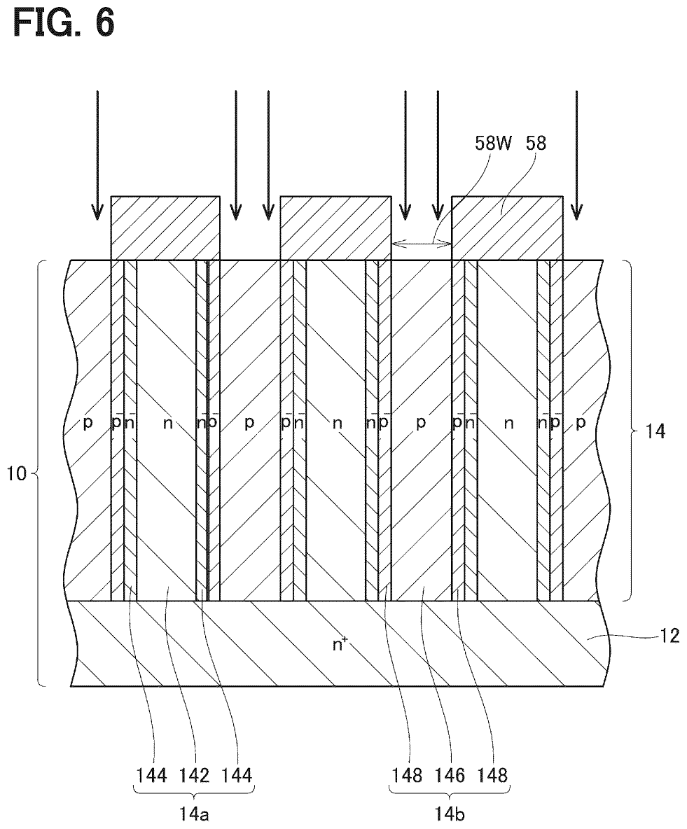

Next, as shown in FIG. 6, a shielding layer 58 is formed on the epitaxial layer 140 using a photolithography technique. The shielding layer 58 is an example of the second shielding layer. The shielding layer 58 is patterned to have openings corresponding to the formation ranges of the p-type column high-concentration layers 146. Here, multiple types of photomasks for exposing the shielding layer 58 are prepared, and an appropriate photomask is selected according to the previously measured opening width 54W of the shielding layer 54 (see FIG. 4). For example, when the measured opening width 54W of the shielding layer 54 is greater than the design value, the opening width tends to be greater than the design value. In this case, therefore, a type of photomask having the opening width smaller than the design value is selected for exposing the shielding layer 58. On the other hand, when the measured opening width 54W of the shielding layer 54 is smaller than the design value, the opening width tends to be smaller than the design value. In this case, therefore, a type of photomask having the opening width greater than the design value is selected for exposing the shielding layer 58. As a result, the opening width 58W of the shielding layer 58 can be made close to the design value. Next, the p-type column high-concentration layer 146 is formed by implanting p-type impurity ions into the epitaxial layer 140 through the openings in the shielding layer 58 using an ion implantation technique. The p-type impurity ions are not particularly limited, but, for example, aluminum ions may be used. As described above, since the opening width 58W of the shielding layer 58 is close to the design value, the carrier concentration of the p-type impurity in the p-type column high-concentration layer 146 is the desired value. After the ion implantation, the shielding layer 58 is removed. It should be noted that the p-type column high-concentration layer 146 may be formed prior to the n-type column high-concentration layer 142.

Through these processes, the super junction structure in which the n-type columns 14a and the p-type columns 14b are alternately arranged in the repeating manner is formed in the semiconductor layer 10. In the manufacturing method described above, the n-type column high-concentration layer 142 and the p-type column high-concentration layer 146 are not formed in a positional relationship where the n-type column high-concentration layer 142 and the p-type column high-concentration layer 146 are in direct contact with each other. Since the n-type column low-concentration layers 144 are provided adjacent to the n-type column high-concentration layer 142, even if the position of the opening in the shielding layer 56 for forming the n-type column high-concentration layer 142 is slightly shifted in the repetition direction, the n-type column high-concentration layer 142 is formed to reside within the range of the n-type column low-concentration layer 144. Similarly, since the p-type column low-concentration layers 148 are provided adjacent to the p-type column high-concentration layer 146, even if the position of the opening in the shielding layer 58 for forming the p-type column high-concentration layer 146 is slightly shifted in the repetition direction, the p-type column high-concentration layer 146 is formed to reside within the range of the p-type column low-concentration layer 148. In this manner, by the manufacturing method described above, even if there is a positional deviation in the shielding layer 56, 58 in the repetition direction, it is less likely that the n-type column high-concentration layer 142 and the p-type column high-concentration layer 146 will be formed to overlap with each other.

As described above, the semiconductor device 1 is designed to ensure the charge balance between the n-type column 14a and the p-type column 14b by achieving the charge balance between the n-type column high-concentration layer 142 and the p-type column high-concentration layer 146. In the semiconductor device 1, it is less likely that the n-type column high-concentration layer 142 and the p-type column high-concentration layer 146 will be formed to overlap each other. Therefore, the disruption of charge balance between the n-type column 14a and the p-type column 14b is suppressed. As such, the semiconductor device 1 manufactured by the method described above can achieve both low on-resistance and high breakdown voltage.

In the manufacturing method described above, it is possible to understand whether the opening widths 52A and 54W of the shielding layers 52 and 54 tend to be greater or smaller than the design values by measuring the opening widths 52W and 54W of the shielding layers 52 and 54. For this reason, by forming the shielding layers 56 and 58 using photomasks that suppress the tendency of the opening widths to be wider or narrower, the opening widths 56W and 58W of the shielding layers 56 and 58 can be made closer to the design values. As a result, it is possible to make the charge amounts of the n-type column high-concentration layer 142 and the p-type column high-concentration layer 146 the desired values. Also in this regard, the semiconductor device 1 manufactured by the method described above can achieve both low on-resistance and high breakdown voltage.

In the manufacturing method described above, a misalignment of the shielding layer 52 may be measured when the shielding layer 52 is formed. The misalignment refers to a positional deviation from a design position in a relative positional relationship with respect to an alignment mark. Although not particularly limited, the misalignment may be, for example, described in a coordinate system defined with reference to the alignment mark. For example, in a case where an XY orthogonal coordinate system is defined with reference to the alignment mark, the misalignment can be described in terms of the positional deviation of two components in the X direction and the Y direction. In the manufacturing method described above, since the misalignment is measured when the shielding layer 52 is formed, it is possible to understand the tendency of the misalignment. Therefore, the shielding layer 56 is formed under a condition that can suppress the tendency of the misalignment. Specifically, the shielding layer 56 is formed at a position that takes the misalignment into account relative to the geometric center of the n-type low-concentration layer so that the geometric center of the n-type low-concentration layer formed corresponding to the formation range of the n-type column 14a and the geometric center of the n-type column high-concentration layer 142 match each other. Therefore, the shielding layer 56 is formed so that the geometric center of the opening of the shielding layer 56 matches the geometric center of the n-type low-concentration layer. As a result, the n-type column high-concentration layer 142 is formed to reside within the range of the n-type low-concentration layer.

Similarly, in the manufacturing method described above, a misalignment of the shielding layer 54 may also be measured when the shielding layer 54 is formed. In the manufacturing method described above, the shielding layer 58 is formed under a condition that can suppress the tendency of the misalignment. Specifically, the shielding layer 58 is formed at a position that takes the misalignment into account relative to the geometric center of the p-type low-concentration layer so that the geometric center of the p-type low-concentration layer formed corresponding to the formation range of the p-type column 14b and the geometric center of the p-type column high-concentration layer 146 match each other. Therefore, the shielding layer 58 is formed so that the geometric center of the opening of the shielding layer 58 matches the geometric center of the p-type low-concentration layer. As a result, the p-type column high-concentration layer 146 is formed to reside within the range of the p-type low-concentration layer.

It is not always necessary that the process of feeding back the misalignment of the shielding layer is performed together with the process of feeding back the opening width of the shielding layer. The process of feeding back the misalignment of the shielding layer may be performed without performing the process of feeding back the opening width of the shielding layer.

### Second Embodiment

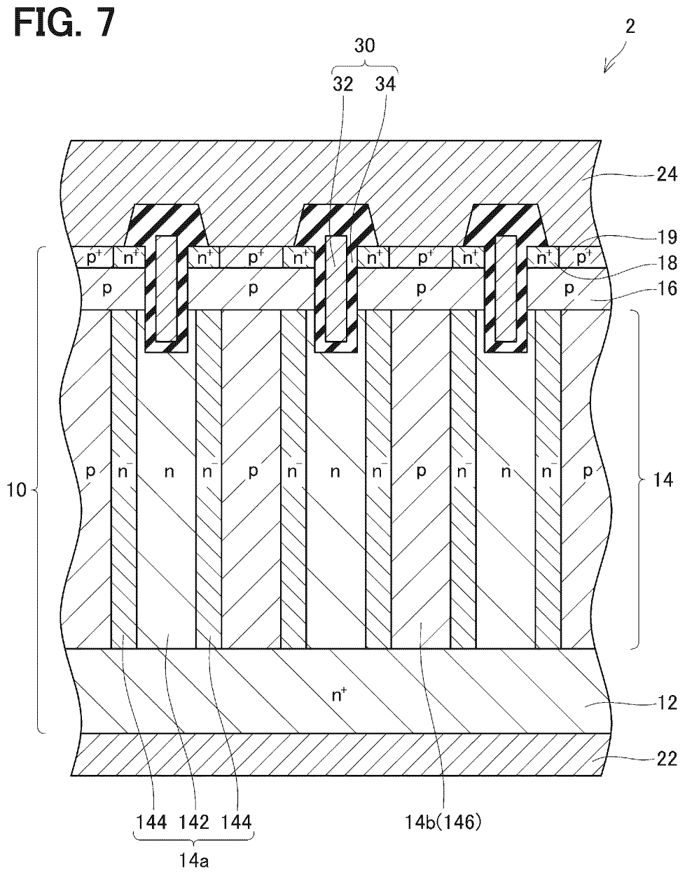

FIG. 7 schematically shows a cross-sectional view of a main part of a semiconductor device 2. The semiconductor device 2 includes the p-type column 14b that is composed solely of the p-type column high-concentration layer 146. That is, the p-type column 14b has a constant concentration distribution of p-type impurity in the repetition direction. Also in this example, since the n-type column low-concentration layer 144 is disposed between the n-type column high-concentration layer 142 and the p-type column high-concentration layer 146, it is less likely that the n-type column high-concentration layer 142 and the p-type column high-concentration layer 146 will be formed to overlap each other. Since the disruption of the charge balance between the n-type column 14a and the p-type column 14b is suppressed, the semiconductor device 2 can achieve both low on-resistance and high breakdown voltage.

It should be noted that the n-type column low-concentration layer 144 may be an epitaxial layer. In this case, the semiconductor device 2 can be manufactured by forming the n-type column high-concentration layer 142 and the p-type column high-concentration layer 146 spaced apart in the repetition direction within the epitaxial layer having a low n-type impurity concentration. Since the number of processes can be reduced, the semiconductor device 2 can be manufactured at a lower cost. In place of the n-type column low-concentration layer 144, a p-type column low-concentration layer may be provided.

### Third Embodiment

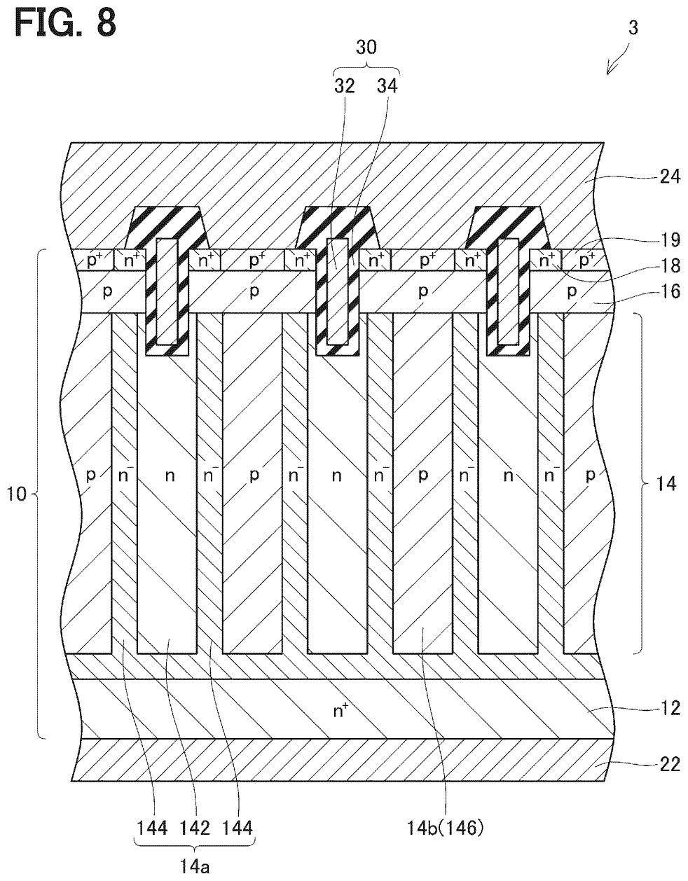

FIG. 8 schematically shows a cross-sectional view of a main part of a semiconductor device 3. The semiconductor device 3 is a modified example of the semiconductor device 2. In the semiconductor device 3, the n-type column low-concentration layer 144 is also adjacent to the bottom surface of the n-type column high-concentration layer 142. In this example, the n-type column low-concentration layer 144 is also adjacent to the bottom surface of the p-type column 14b. In the semiconductor device 3, even if the bottom surface of the p-type column 14b is formed deeply, since the n-type column low-concentration layer 144 is provided adjacent to the bottom surface of the n-type column high-concentration layer 142, it is possible to suppress the increase in resistance due to the JFET effect. It is to be noted that the p-type column low-concentration layer may be provided so as to be in contact with the bottom surface of the p-type column high-concentration layer 146.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A semiconductor device comprising:
a semiconductor layer having a super junction structure in which a first column of a first conductivity type and a second column of a second conductivity type are alternately and repeatedly arranged in at least one direction, wherein
the first column is an n-type column,
the second column is a p-type column,
the first column includes a first column high-concentration layer and a first column low-concentration layer that is disposed adjacent to both side surfaces of the first column high-concentration layer in the at least one direction and has a carrier concentration lower than a carrier concentration of the first column high-concentration layer, and
the second column includes a second column high-concentration layer and a second column low-concentration layer that is disposed adjacent to both side surfaces of the second column high-concentration layer in the at least one direction and has a carrier concentration lower than a carrier concentration of the second column high-concentration layer.

2. The semiconductor device according to claim 1, wherein
the carrier concentration of the first column low-concentration layer is one-fifth or less of the carrier concentration of the first column high-concentration layer.

3. The semiconductor device according to claim 1, wherein
the first column low-concentration layer is also adjacent to a bottom surface of the first column high-concentration layer.

4. The semiconductor device according to claim 1, wherein
the first column low-concentration layer is also adjacent to a bottom surface of the second column.

5. A method for manufacturing a semiconductor device, the semiconductor device including a semiconductor layer that has a super junction structure in which a first column of a first conductivity type and a second column of a second conductivity type are alternately and repeatedly arranged in at least one direction, and in which the first column includes a first column high-concentration layer and a first column low-concentration layer that is disposed adjacent to the first column high-concentration layer in the at least one direction and has a carrier concentration lower than a carrier concentration of the first column high-concentration layer,
the method comprising:
forming a first shielding layer on a surface of the semiconductor layer, the first shielding layer having an opening corresponding to a formation range where the first column is to be formed;
measuring a misalignment of the first shielding layer;
implanting ions into the semiconductor layer through the opening of the first shielding layer;
forming a second shielding layer on the surface of the semiconductor layer, the second shielding layer having an opening corresponding to a formation range where the first column high-concentration layer is to be formed according to the measured misalignment; and
implanting ions into the semiconductor layer through the opening of the second shielding layer.

6. A method for manufacturing a semiconductor device, the semiconductor device including a semiconductor layer that has a super junction structure in which a first column of a first conductivity type and a second column of a second conductivity type are alternately and repeatedly arranged in at least one direction, and in which the first column includes a first column high-concentration layer and a first column low-concentration layer that is disposed adjacent to the first column high-concentration layer in the at least one direction and has a carrier concentration lower than a carrier concentration of the first column high-concentration layer,
the method comprising:
forming a first shielding layer on a surface of the semiconductor layer, the first shielding layer having an opening corresponding to a formation range where the first column is to be formed;
measuring a width of the opening of the first shielding layer;
implanting ions into the semiconductor layer through the opening of the first shielding layer;
forming a second shielding layer on the surface of the semiconductor layer, the second shielding layer having an opening corresponding to a formation range where the first column high-concentration layer is to be formed according to the measured width; and
implanting ions into the semiconductor layer through the opening of the second shielding layer.
